(19) United States
(12) Patent Application Publication
(10) Pub. No.: US 2016/0320713 A1
(43) Pub. Date: Nov. 3, 2016

(54) SUBSTRATE TREATMENT SYSTEM, SUBSTRATE TRANSFER METHOD, AND COMPUTER STORAGE MEDIUM

(71) Applicant: TOKYO ELECTRON LIMITED, Tokyo (JP)

(72) Inventors: Takuya MORI, Minato-ku, Tokyo (JP); Masaru TOMONO, Koshi City, Kumamoto (JP)

(21) Appl. No.: 15/105,132

(22) PCT Filed: Oct. 30, 2014
(86) PCT No.: PCT/JP2014/078909

§ 371 Date: Jun. 16, 2016

(30) Foreign Application Priority Data
Dec. 26, 2013 (JP) 2013-269251

(51) Int. Cl. G03F 7/20; H01L 21/67; H01L 21/66; H01L 21/677

(52) U.S. Cl. CPC G03F 7/70633; H01L 21/67745; H01L 21/67178; H01L 22/12

(57) ABSTRACT

A substrate treatment system includes: a treatment station including a plurality of treatment apparatuses; an interface station which delivers a substrate to/from an exposure apparatus provided outside the system and including a plurality of exposure stages; a plurality of substrate inspection apparatuses; a substrate transfer mechanism which transfers the substrate between each of the treatment apparatuses in the treatment station and the substrate inspection apparatus; and a control apparatus which identifies an exposure stage which has been used in exposure processing of a substrate from among the plurality of exposure stages, and controls the substrate transfer mechanism to transfer the substrate after the exposure processing to a substrate inspection apparatus previously made to correspond to the identified exposure stage.

### TECHNICAL FIELD

### Cross-Reference to Related Applications

This application is based upon and claims the benefit of priority of the prior Japanese Patent Application No. 2013-269251, filed in Japan on Dec. 26, 2013, the entire contents of which are incorporated herein by reference.

The present invention relates to a substrate treatment system, a substrate transfer method, and a computer storage medium.

### BACKGROUND ART

In photolithography processing in a manufacturing process of a semiconductor device, for example, various treatments such as resist coating treatment for applying a resist solution, for example, on a substrate such as a semiconductor wafer (hereinafter, referred to as a “wafer”) to form a resist film, exposure processing for exposing a predetermined pattern on the resist film, developing treatment for developing the exposed resist film, heat treatment for drying the wafer after the developing treatment and so on are performed. A series of the treatments is performed in a coating and developing treatment system being a substrate treatment system in which the various treatment units which treat the substrate and transfer units which transfer the wafer are installed, and an exposure apparatus provided adjacent to the coating and developing treatment system.

The throughput of the above-described photolithography processing is generally rate-controlled depending on the processing ability of the exposure apparatus. Therefore, in order to improve the throughput of the exposure processing in the exposure apparatus, two stages are provided in the exposure apparatus (Patent Document 1).

Incidentally, in manufacture of the semiconductor device, it is necessary to limit an overlay error between a pattern already formed on the wafer and a pattern exposed thereafter in a predetermined range. For this end, for exposure processing, the overlay error is measured and parameters and so on for exposure processing thereafter are decided based on the error (Patent Document 2).

### PRIOR ART DOCUMENT

### Patent Document

[Patent Document 1] U.S. Pat. No. 5,969,411

[Patent Document 2] Japanese Translation of PCT International Application No. 2013-515819

### DISCLOSURE OF THE INVENTION

### Problems to be Solved by the Invention

However, accompanying microfabrication of the semiconductor device in recent years, the number of measurement points for the overlay error tends to increase. Therefore, a plurality of measuring instruments for overlay measurement are sometimes installed, for example, in the above-described coating and developing treatment system. In this case, the wafer which has been subjected to exposure processing in the exposure apparatus and subjected to various treatments such as developing treatment, heat treatment and so on in the coating and developing treatment system is subjected to measurements in sequence in the measuring instruments. Then, the results are reflected lot by lot, for example, in the exposure apparatus side.

However, it has been confirmed by the present inventors that measured results in the measuring instruments include inevitable measurement errors unique to the respective measuring instruments, and same measured results among the measuring instruments cannot be obtained even if correction of errors is performed. Therefore, there is a problem in which when a plurality of wafers included in the same lot are measured by a plurality of different measuring instruments, the overlay error is not sufficiently improved even when the measured results are reflected in parameters and so on for exposure processing subsequent thereto.

The present invention has been made in consideration of the above points, and its object is to improve an error in substrate inspection by appropriately performing substrate inspection after exposure processing.

### Means for Solving the Problems

To achieve the above object, the present invention is a substrate treatment system for treating a substrate, including: a treatment station in which a plurality of treatment apparatuses that treat the substrate are provided; an interface station which delivers the substrate between the treatment station and an exposure apparatus which is provided outside the substrate treatment system and includes a plurality of exposure stages; a plurality of substrate inspection apparatuses which perform inspection of a substrate front surface; a substrate transfer mechanism which transfers the substrate between each of the treatment apparatuses in the treatment station and the substrate inspection apparatus; and a controller which controls the substrate transfer mechanism. The controller is configured to identify an exposure stage which has been used in exposure processing of a substrate transferred out of the exposure apparatus, from among the plurality of exposure stages, and control the substrate transfer mechanism to transfer the substrate after the exposure processing to a substrate inspection apparatus previously made to correspond to the identified exposure stage.

According to the present invention, an exposure stage which has been used in exposure processing is identified and the substrate is transferred to a substrate inspection apparatus previously made to correspond to the identified exposure stage, so that the substrate which has been subjected to exposure processing on a predetermined exposure stage is inspected in the same substrate inspection apparatus at all times. Therefore, for example, when the overlay error is measured in the substrate inspection apparatus, the measurement error included in a measure result can be made constant at all times and a stable inspection result can be provided to the exposure apparatus side. As a result, the overlay error in exposure processing can be improved.

The present invention according to another aspect is a method for transferring a substrate in a substrate treatment system for treating a substrate, the substrate treatment system including: a treatment station in which a plurality of treatment apparatuses are provided; an interface station which delivers the substrate between the treatment station and an exposure apparatus which is provided outside the substrate treatment system and includes a plurality of exposure stages; a plurality of substrate inspection apparatuses which perform inspection of a substrate front surface; and a substrate transfer mechanism which transfers the substrate between each of the treatment apparatuses in the treatment station and the substrate inspection apparatus. The present invention, in the substrate treatment system, identifies an exposure stage which has been used in exposure processing of a substrate transferred out of the exposure apparatus, from among the plurality of exposure stages, and transfers the substrate after the exposure processing to a substrate inspection apparatus previously made to correspond to the identified exposure stage.

The present invention according to another aspect is a computer readable storage medium storing a program running on a computer of a control apparatus controlling the substrate treatment system to cause the substrate treatment system to execute the substrate transfer method.

### Effect of the Invention

According to the present invention, it is possible to improve an error in substrate inspection by appropriately performing substrate inspection after exposure processing.

### BRIEF DESCRIPTION OF THE DRAWINGS

FIG. 1 A plan view illustrating the outline of a configuration of a coating and developing treatment system according to an embodiment.

FIG. 2 A side view illustrating the outline of the configuration of the coating and developing treatment system according to the embodiment.

FIG. 3 A side view illustrating the outline of the configuration of the coating and developing treatment system according to the embodiment.

FIG. 4 An explanatory view illustrating an example of a transfer route table.

FIG. 5 An explanatory view illustrating an example of the transfer route table.

FIG. 6 An explanatory view illustrating an example of the transfer route table.

FIG. 7 A flowchart about inspection and transfer of a wafer.

FIG. 8 An explanatory view illustrating a storage state of wafers in a wafer mounting unit.

### BEST MODE FOR CARRYING OUT THE INVENTION

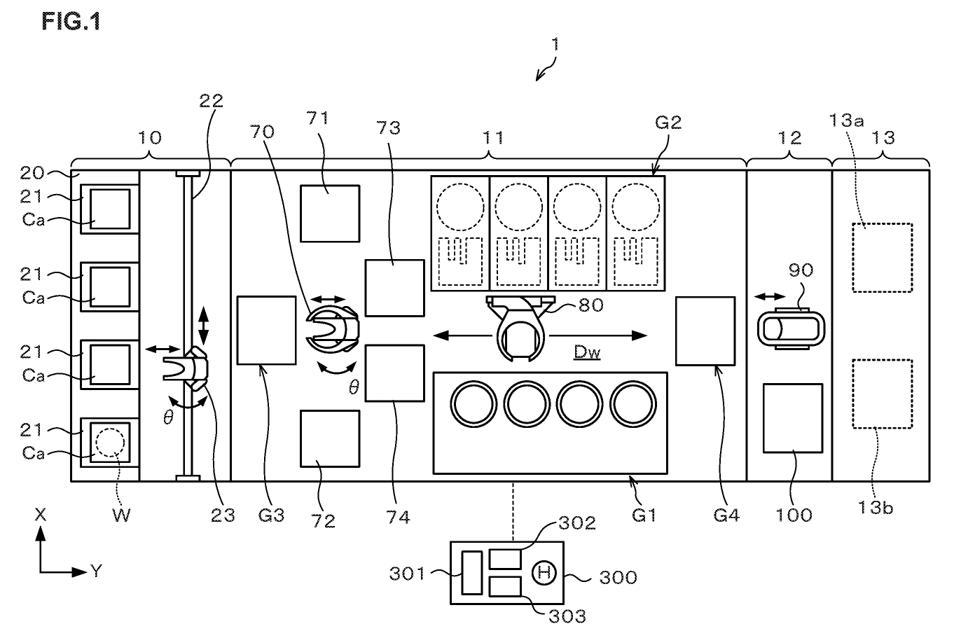

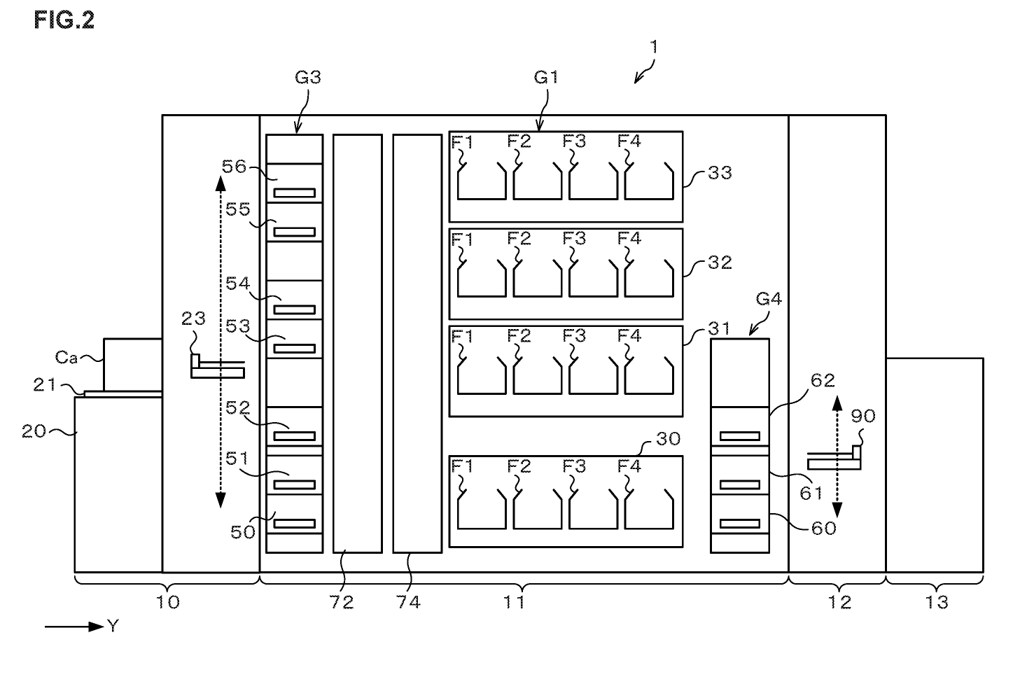

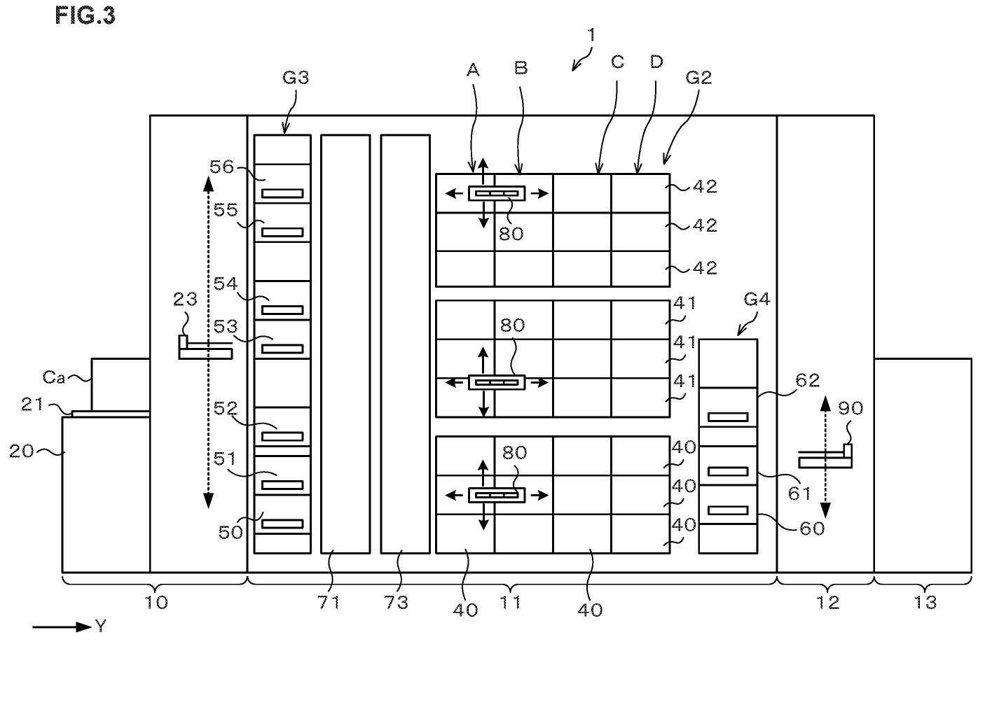

Hereinafter, an embodiment of the present invention will be described. FIG. 1 is an explanatory view illustrating the outline of a configuration of a coating and developing treatment system 1 as a substrate treatment system according to the embodiment, and FIG. 2 and FIG. 3 are side views illustrating the outline of an internal configuration of the coating and developing treatment system 1 respectively.

The coating and developing treatment system 1 has a configuration, as illustrated in FIG. 1, in which a cassette station 10 into/out of which a cassette Ca that houses a plurality of wafers W is transferred, a treatment station 11 including a plurality of various treatment apparatuses which perform predetermined treatments on the wafer W, and an interface station 12 provided adjacent to the treatment station 11, are integrally connected. An exposure apparatus 13 is provided adjacently on the positive direction side in a Y-direction of the interface station 12. The interface station 12 delivers the wafer W to/from the exposure apparatus 13. The exposure apparatus 13 is provided with, for example, two exposure stages 13a, 13b. Note that the number of exposure stage is not limited to this embodiment, but three or more exposure stages may be provided.

In the cassette station 10, a plurality of cassette mounting plates 21 which are arranged on a cassette mounting table 20 and on which the cassettes Ca are mounted, and a wafer transfer apparatus 23 which is movable on a transfer path 22 extending in an X-direction are provided. The wafer transfer apparatus 23 is movable also in a vertical direction and around a vertical axis (in a θ-direction), and can transfer the wafer W between the cassette Ca on each of the cassette mounting plates 21 and a later-described delivery apparatus in a third block G3 in the treatment station 11.

In the treatment station 11, a plurality of, for example, four blocks G1, G2, G3, G4 are provided each including various apparatuses. For example, in the first block G1, as illustrated in FIG. 2, a plurality of solution treatment apparatuses, for example, lower anti-reflection film forming apparatuses 30 each of which forms an anti-reflection film (hereinafter, referred to as a “lower anti-reflection film”) at a lower layer of a resist film of the wafer W, resist coating apparatuses 31 each of which applies a resist solution to the wafer W to form a resist film, upper anti-reflection film forming apparatuses 32 each of which forms an anti-reflection film (hereinafter, referred to as an “upper anti-reflection film”) at an upper layer of the resist film of the wafer W, and developing treatment apparatuses 33 each of which performs developing treatment on the wafer W, are four-tiered, for example, in order from the bottom.

Each of the apparatuses 30 to 33 in the first block G1 has a plurality of cups, for example, four cups F1, F2, F3, F4 which house wafers W therein during treatment, in this order from the left side to the right side in the horizontal direction, and thus can treat a plurality of wafers W in parallel.

For example, in the second block G2, as illustrated in FIG. 3, thermal treatment apparatuses 40 each of which performs thermal treatment on the wafer W, adhesion apparatuses 41 as hydrophobic treatment apparatuses each of which performs hydrophobic treatment on the wafer W, and edge exposure apparatus 42 each of which exposes the outer peripheral portion of the wafer W, are arranged one on top of the other in the vertical direction and side by side in the horizontal direction. The thermal treatment apparatus 40 has a hot plate which mounts and heats the wafer W thereon and a cooling plate which mounts and cools the wafer W thereon, and thereby can perform both of heat treatment and cooling treatment. Each of the treatment apparatuses 40 to 42 provided stacked as illustrated in FIG. 3 is divided into a module A, a module B, a module C, and a module D in this order from the left side to the right side in the horizontal direction, and can perform treatment on the wafer W independently in each of the modules A to D.

For example, in the third block G3, a plurality of delivery apparatuses 50, 51, 52, 53, 54, 55, 56 are provided in order from the bottom. Further, in the fourth block G4, a plurality of delivery apparatuses 60, 61, 62 are provided in order from the bottom.

As illustrated in FIG. 1, adjacent on the positive direction side in the Y-direction of the third block G3, a wafer transfer mechanism 70 is provided. The wafer transfer mechanism 70 has a transfer arm that is movable, for example, in the Y-direction, the θ-direction, and the vertical direction. On the positive direction side and the negative direction side in the X-direction of the wafer transfer mechanism 70, wafer inspection apparatuses 71, 72 are provided across the wafer transfer mechanism 70. Further, on the positive direction side in the Y-direction of the wafer transfer mechanism 70, wafer mounting units (buffers) 73, 74 each of which temporarily houses a plurality of wafers W are provided. The wafer mounting unit 73 is disposed closer to the second block G2, and the wafer mounting unit 74 is disposed closer to the first block G1. The wafer transfer mechanism 70 can vertically move while supporting the wafer W to transfer the wafer W among the delivery apparatuses in the third block G3, the wafer inspection apparatuses 71, 72, and the wafer mounting units 73, 74. Note that the wafer inspection apparatuses 71, 72 in this embodiment measure an overlay error between a pattern already formed on the wafer W and a pattern exposed thereafter.

As illustrated in FIG. 1, in a region surrounded by the first block G1, the second block G2, the fourth block G4, and the wafer mounting units 73, 74, a wafer transfer region Dw is formed. In the wafer transfer region Dw, a plurality of wafer transfer mechanisms 80 are arranged. The wafer transfer mechanism 80 has a transfer aim movable, for example, in the Y-direction, the X-direction, the θ-direction, and the vertical direction. The wafer transfer apparatus 80 can move in the wafer transfer region Dw to transfer the wafer W to a predetermined apparatus in the first block G1, the second block G2, and the fourth block G4, and the wafer housing containers 73, 74 therearound.

In the interface station 12, a wafer transfer mechanism 90 and a delivery apparatus 100 are provided. The wafer transfer mechanism 90 has a transfer arm movable, for example, in the Y-direction, the θ-direction, and the vertical direction. The wafer transfer mechanism 90 can transfer the wafer W among each of the delivery apparatuses in the fourth block G4, the delivery apparatus 100, and the exposure apparatus 13, while supporting the wafer W on the transfer arm.

In the above coating and developing treatment system 1, a controller 300 is provided as illustrated in FIG. 1. The controller 300 has a storage means 301 which stores a treatment recipe for each lot of the wafers W therein, a transfer processing control means 302 which controls the operations of the various treatment apparatuses and the driving systems such as the wafer transfer mechanisms on the basis of the treatment recipe, and a communication means 303 which communicates with a controller (not illustrated) of the exposure apparatus 13.

The transfer processing control means 302 decides a transfer route for the wafer W on the basis of the treatment recipe for the wafer W stored in the storage means 301. Hereinafter, the way to decide the transfer route for the wafer W will be described divided into the one before exposure processing in the exposure apparatus 13 and the one after the exposure processing.

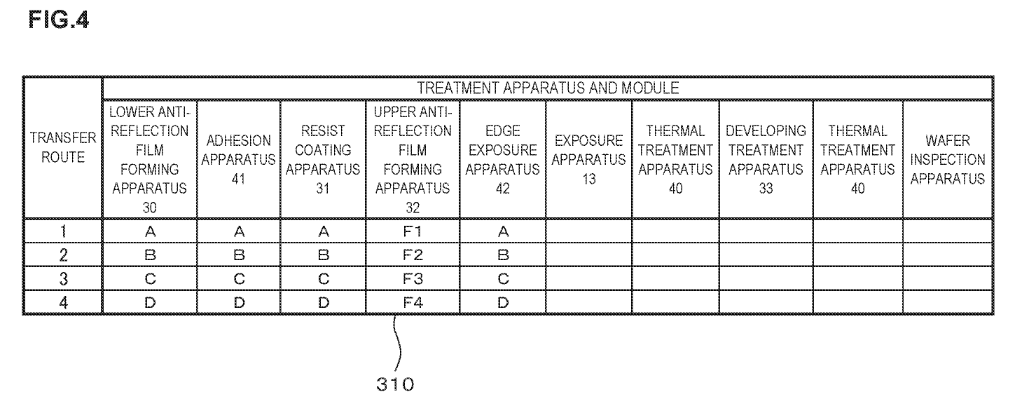

For deciding the transfer route before exposure processing, the transfer processing control means 302 decides, according to the treatment recipe, a transfer route from the formation of a lower anti-reflection film to the edge exposure processing being the processing before exposure processing, namely, from the lower anti-reflection film forming apparatus 30 to the adhesion apparatus 41, the resist coating apparatus 31, the upper anti-reflection film forming apparatus 32, and the edge exposure apparatus 42, for example, as illustrated in FIG. 4. Hereinafter, the transfer route illustrated in FIG. 4 is referred to as a transfer route table 310. In a portion of each square of the transfer route table 310, a module which performs treatment on the wafer W in each treatment apparatus is indicated. The module referred to here is each of the cups F1 to F4, for example, in the lower anti-reflection film forming apparatus 30, or each of the modules A to D, for example, in the adhesion apparatus 41. Note that in the transfer route table 310, the thermal treatment apparatus 40 to which the wafer W is transferred before exposure processing is not indicated, but the thermal treatment on the wafer W before exposure processing is to be performed at appropriate time between treatments in the apparatuses, and its description and indication will be omitted here. Further, the transfer route after exposure processing is not decided yet at this point in time, and therefore the transfer route after the exposure apparatus 13 is not indicated in the transfer route table 310 in FIG. 4.

The transfer route in the transfer route table 310 is decided based on the treatment recipe for the wafer W as described above, and a module being a transfer destination is decided based on a predetermined rule. The transfer route table 310 illustrated in FIG. 4 illustrates an example of the case decided based on, for example, a rule that the wafer W transferred to the cup F1 of the lower anti-reflection film forming apparatus 30 is transferred to the cup F1 and the module A in subsequent treatments, and the wafers W transferred to the cups F2 to F4 are transferred to the cups F2 to F4 and the modules B to D in subsequent treatments respectively.

Next, the decision of the transfer route after exposure processing will be described. The wafer W transferred from the edge exposure apparatus 42 to the exposure apparatus 13 is mounted on either the exposure stage 13a or the exposure stage 13b in the exposure apparatus 13 and then subjected to exposure processing. In this event, which of the exposure stage 13a and the exposure stage 13b the wafer W is mounted on is decided by the controller in the exposure apparatus 13. After the finish of the exposure processing, the wafer W is transferred by the wafer transfer mechanism 90 from the exposure apparatus 13 to the treatment station 11, and information about on which of the exposure stage 13a and the exposure stage 13b the exposure processing has been performed is inputted from the exposure apparatus 13 into the controller 300 via the communication means 303.

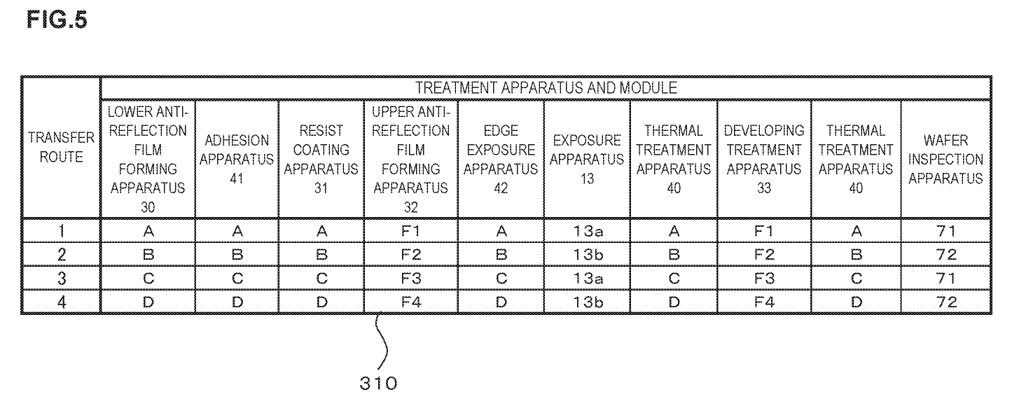

In the transfer processing control means 302, the exposure stage which has been used for the exposure processing and the inspection apparatus which inspects the wafer W which has been subjected to the exposure processing on the exposure stage, are previously made to correspond to each other. Then, the transfer processing control means 302 decides the transfer route to transfer the wafer W after exposure processing to the corresponding inspection apparatus on the basis of the information about the exposure stage inputted into the controller 300. In this embodiment, for example, the exposure stage 13a and the wafer inspection apparatus 71 are previously made to correspond to each other, and the exposure stage 13b and the wafer inspection apparatus 72 are previously made to correspond to each other. Therefore, the transfer processing control means 302 decides the transfer route so that the wafer W which has been subjected to the exposure processing on the exposure stage 13a is transferred to the wafer inspection apparatus 71 and the wafer W which has been subjected to the exposure processing on the exposure stage 13b is transferred to the wafer inspection apparatus 72 as indicated, for example, in the transfer route table 310 in FIG. 5. Thus, the wafer W which has been subjected to the exposure processing on a predetermined exposure stage is inspected at all times in the wafer inspection apparatus previously made to correspond thereto. Therefore, for example, when the measurement of the overlay error is performed in the wafer inspection apparatus 71, 72, the error included in the measured result becomes constant at all times.

Note that in the transfer route table 310 illustrated in FIG. 5, the wafer W which has been treated in the cup F1 of the resist coating apparatus before exposure processing is to be transferred to the cup F1 with the same code in the developing treatment apparatus 33 also in the developing treatment after exposure processing, and the module to which the wafer W is to be transferred after exposure processing may be previously made to correspond to the exposure stage which has been used for the exposure processing as in the case of the wafer inspection apparatus 71, 72 so that the wafer W is transferred to the module are made to correspond thereto. More specifically, for example, the wafer W which has been subjected to exposure processing on the exposure stage 13a may be transferred to any one of the cup F1 and the cup F3 of the developing treatment apparatus 33, and the wafer W which has been subjected to exposure processing on the exposure stage 13b may be transferred to any of the cup F2 and the cup F4 of the developing treatment apparatus 33. Further, also for the thermal treatment apparatus 40, the wafer W is preferably transferred to the module similarly previously made to correspond to the exposure stage. Generally, variations unique to an apparatus (module) are generated in the treatment result due to manufacturing error or the like of each treatment apparatus, but deciding in advance the transfer route after exposure processing makes it possible to make the variations among the modules constant, resulting in minimization of the variations in measured results in the wafer inspection apparatus 71, 72. Note that the correspondence between the exposure stage and each treatment apparatus may be established for treatments before exposure processing.

Note that the above-described controller 300 is composed of, for example, a computer having a CPU, a memory and so on and can execute programs stored, for example, in the memory to implement the coating treatment in the coating and developing treatment system 1. Note that various programs for implementing the coating treatment in the coating and developing treatment system 1 may be the ones which are stored, for example, in a storage medium H such as a computer-readable hard disk (HD), flexible disk (FD), compact disk (CD), magneto-optical disk (MO), or memory card, and installed from the storage medium H into the controller 300.

Next, a method for transferring the wafer W performed in the coating and developing treatment system 1 configured as described above will be described together with the process of the wafer treatment performed in the whole coating and developing treatment system 1. Note that the following description will be made taking, as an example, the case of performing treatment on the wafer W following a transfer route No. 1 illustrated in FIG. 5.

For treating the wafer W, first, a cassette Ca housing a plurality of wafers W therein is mounted on a predetermined mounting plate 21 in the cassette station 10. Thereafter, the wafers W in the cassette Ca are sequentially taken out by the wafer transfer apparatus 23 and transferred to the third block G3 in the treatment station 11.

Next, the wafer W is transferred by the wafer transfer mechanism 70, for example, to the wafer mounting unit 73. Then, the wafer W is transferred by the wafer transfer mechanism 80 to the module A of the thermal treatment apparatus 40 in the second block G2 and temperature-regulated. Thereafter, the wafer W is transferred by the wafer transfer mechanism 80, for example, to the module A of the lower anti-reflection film forming apparatus 30 in the first block G1, in which a lower anti-reflection film is formed on the wafer W. The wafer W is thereafter transferred to the module A of the thermal treatment apparatus 40 in the second block G2 and subjected to heat treatment.

The wafer W is thereafter transferred to the module A of the adhesion apparatus 41 in the second block G2 and subjected to hydrophobic treatment. The wafer W is thereafter transferred by the wafer transfer apparatus 80 to the module A of the resist coating apparatus 31, in which a resist film is formed on the wafer W. The wafer W is thereafter transferred to the module A of the thermal treatment apparatus 40 and subjected to pre-baking treatment.

Next, the wafer W is transferred to the module A of the upper anti-reflection film forming apparatus 32, in which an upper anti-reflection film is formed on the wafer W. The wafer W is thereafter transferred to the module A of the thermal treatment apparatus 40, and heated and temperature-regulated. Thereafter, the wafer W is transferred to the module A of the edge exposure apparatus 42 and subjected to edge exposure processing.

Next, the wafer W is transferred to the fourth block G4, and transferred by the wafer transfer mechanism 90 in the interface station 12 to the exposure apparatus 13. In the exposure apparatus 13, the wafer W is mounted, for example, on any one of the exposure stages 13a, 13b. In this embodiment, the wafer W is mounted on the exposure stage 13a and subjected to exposure processing. The wafer W for which the exposure processing has been completed is transferred by the wafer transfer mechanism 90 to the fourth block G4. Additionally, information about the exposure stage which has been used for the exposure processing on the wafer W is inputted into the controller 300 of the coating and developing treatment system 1 from the controller of the exposure apparatus 13 via the communication means 303. Thus, the transfer processing control means 302 identifies the exposure stage which has been used for the exposure processing as the exposure stage 13a, and decides the cup F1 of the developing treatment apparatus 33, the module A of the thermal treatment apparatus 40, and the wafer inspection apparatus 71 previously made to correspond to the exposure stage 13a, as a transfer route thereafter. As a result, a transfer route as indicated, for example, at “No. 1” of the transfer route table 310 in FIG. 5 is decided.

The wafer W is thereafter transferred by the wafer transfer mechanism 80 to the module A of the thermal treatment apparatus 40 and subjected to post-exposure baking treatment. The wafer W is thereafter transferred to the cup F1 of the developing treatment apparatus 33 made to correspond to the exposure stage 13a and subjected to developing treatment. After the developing treatment is finished, the wafer W is transferred to the module A of the thermal treatment apparatus 40 and subjected to post-baking treatment.

The wafer W is thereafter transferred to the wafer mounting unit 73. The wafer W is then transferred by the wafer transfer mechanism 70 to the wafer inspection apparatus 71 and subjected to measurement of the overlay error. The overlay error measured in the wafer inspection apparatus 71 is managed, for example, lot by lot, and transmitted, for example, as feedback information to the exposure apparatus 13 via the communication means 303.

The wafer W is thereafter transferred by the wafer transfer mechanism 70 to the third block G3, and thereafter transferred by the wafer transfer apparatus 23 in the cassette station 10 to the cassette Ca on a predetermined cassette mounting plate 21. Further, the treatment process is performed also on the other wafers W in the same lot, with which a series of photolithography processing ends.

According to the above embodiment, the exposure stage which has been used for the exposure processing is identified by the transfer processing control means 302 of the controller 300, and the wafer W is transferred to the wafer inspection apparatus previously made to correspond to the identified exposure stage, so that, for example, the wafer W which has been subjected to the exposure processing on the exposure stage 13a is subjected to measurement of the overlay error in the wafer inspection apparatus 71 previously made to correspond thereto. Therefore, it is possible to make the measurement error unique to the wafer inspection apparatus 71, 72 included in the measured result constant at all times, and provide stable feedback information to the exposure apparatus 13 side. As a result, the overlay error in exposure processing can be improved.

Further, not only to the wafer inspection apparatus 71, 72, but also in the treatment apparatus in which treatment is performed after the exposure processing, the wafer W is transferred to a module corresponding to the identified exposure stage. Therefore, it is possible to make the variations generated among modules in each treatment apparatus constant, thereby minimizing the variations in measured result in the wafer inspection apparatus 71, 72.

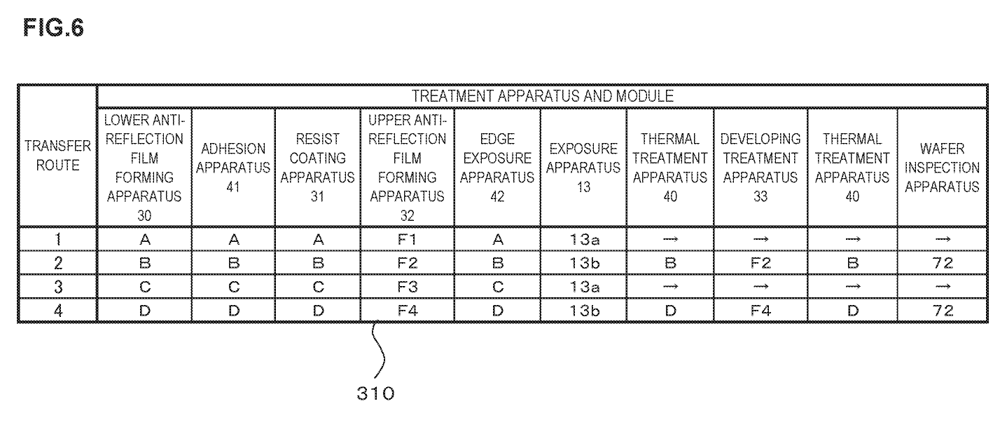

Note that in the case where any one of the exposure stages 13a, 13b in the exposure apparatus 13 has become unusable any longer, the inspection of the wafer W may be continued only in the wafer inspection apparatus corresponding to the usable exposure stage, and the inspection in the wafer inspection apparatus corresponding to the exposure stage which has become unusable any longer may be stopped. In other words, the exposure stage which has been used in the exposure processing is identified and the wafer W for which the transfer route in the transfer route table 310 has been decided may be transferred according to the decided transfer route regardless of the state of the wafer inspection apparatus not in a correspondence relation with the wafer W. In this case, for example, if a trouble occurs in the exposure stage 13a, the wafer W corresponding to the exposure stage 13a may be transferred to the cassette Ca in the cassette station 10 while bypassing all of the treatments after exposure processing as indicated in a transfer route table 310 in FIG. 6. Note that in FIG. 6, a “rightward arrow” is indicated in a square of a treatment apparatus to be bypassed. For example, if one of the exposure stages has become unusable any longer, inspections of the wafers W which have been subjected to exposure processing on the other exposure stage are dividedly performed by the two wafer inspection apparatuses 71, 72, leading to an improved throughput of inspection itself. However, as has been described above, inspection performed in the wafer inspection apparatus not corresponding to the exposure stage causes an error in the inspection result to fail to obtain useful inspection result, and therefore it is preferable to stop the inspection in the wafer inspection apparatus corresponding to the exposure stage which has become unusable any longer.

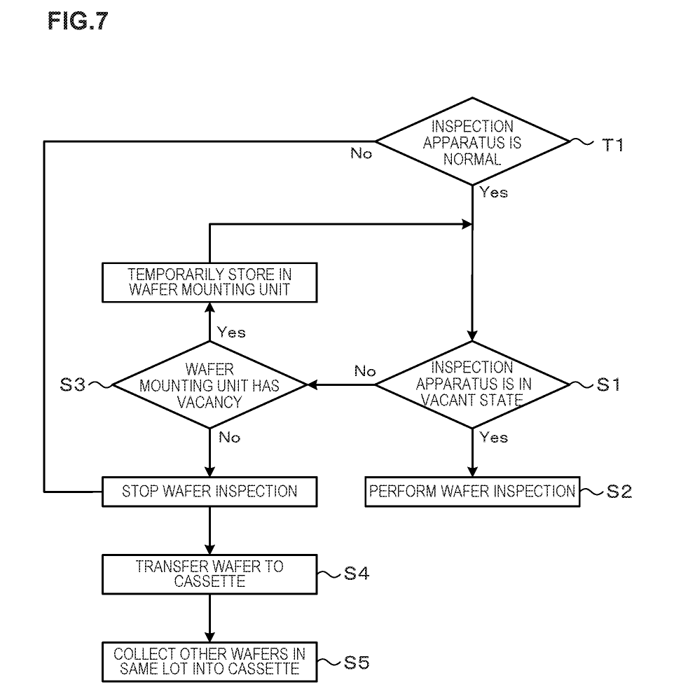

Note that there is a case where the speed of the inspection of the wafer W performed in the wafer inspection apparatus 71, 72 is lower than the speed of exposure processing performed on the exposure stage 13a, 13b. The transfer of the wafer W in such a case will be described with FIG. 7. FIG. 7 is a flowchart about inspection and transfer of the wafer W. Note that a case where the exposure processing is performed on the exposure stage 13a and the inspection of the wafer W is performed in the wafer inspection apparatus 71 is described by way of example. For example, when the wafer W is delivered to the wafer transfer mechanism 70, the controller 300 determines whether or not another wafer W is under inspection in the wafer inspection apparatus 71, in other words, whether or not the wafer inspection apparatus 71 is in a vacant state to be able to inspect the wafer W delivered to the wafer transfer mechanism 70 (S1 in FIG. 7). When the wafer inspection apparatus 71 is determined to be in a state to be able to inspect the wafer W, the wafer W on the wafer transfer mechanism 70 is transferred as it is to the wafer inspection apparatus 71 and subjected to inspection (S2 in FIG. 7). When the wafer inspection apparatus 71 is in use, namely, when another wafer W is being inspected in the wafer inspection apparatus 71, the wafer W is not allowed to be transferred to the wafer inspection apparatus 71, and therefore the wafer W before inspection is temporarily stored in the wafer mounting unit 73 by the wafer transfer mechanism 70 in order to absorb the difference between processing speeds of the exposure processing and the wafer inspection. Note that in this event, the controller 300 determines whether or not the wafer mounting unit 73 has a vacancy for storing the wafer W (S3 in FIG. 7). Then, when the wafer W which has been under inspection in the wafer inspection apparatus 71 is transferred out and the wafer inspection apparatus 71 becomes a vacant state, the wafer W temporarily stored in the wafer mounting unit 73 is transferred to the wafer inspection apparatus 71 and inspected.

Besides, when the number of wafers W stored in the wafer mounting unit 73 increases to reach the upper limit of a storage capacity and there is no more vacancy in the wafer mounting unit 73, the controller 300 may perform control to stop the inspection in the wafer inspection apparatus 71 on the wafer W delivered to the wafer transfer mechanism 70 so as to avoid congestion of subsequent wafers W in the same lot in the coating and developing treatment system 1. The controller 300 controls the wafer transfer mechanisms so as to transfer the wafer W on which the inspection is stopped, directly to the cassette Ca in the cassette station 10 while bypassing, for example, the wafer inspection apparatus 71 (S4 in FIG. 7). Further, when there occurs a wafer W bypassing the wafer inspection apparatus 71 due to the stop of the inspection, all of wafers W in the lot to which the wafer W belongs may be collected into the cassette Ca in the cassette station 10 without being inspected in the wafer inspection apparatus 71, 72 (S5 in FIG. 7). The wafers W in the lot to which the bypassing wafer W belongs here include, for example, the wafer W which has already been temporarily stored in the wafer mounting unit 73 as well as the subsequent wafers W in the same lot with the wafer W transferred to the cassette Ca at S4 in FIG. 7.

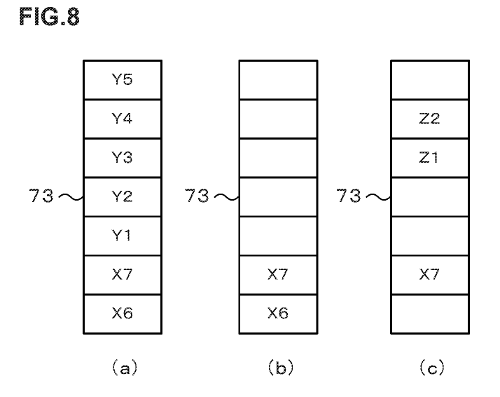

Conventionally, even when there occurs a wafer W bypassing the wafer inspection apparatus 71, subsequent wafers W in the same lot are transferred to vacant places at any time if there are vacancies in the wafer inspection apparatus 71 and the wafer mounting units 73, 74. However, the lot bypassing the wafer inspection apparatus 71 becomes deficient in amount of information fed back to the exposure apparatus 13. Therefore, it is necessary to additionally perform inspection again on the wafers W in the same lot in another inspection apparatus outside the coating and developing treatment system 1, and feed its result back to the exposure apparatus 13 side. Accordingly, it is more preferable to transfer the wafers W in the lot, in which a wafer W bypassing the wafer inspection apparatus 71, 72 occurs, speedily out of the coating and developing treatment system 1 and thereby ensure a vacant capacity of the wafer mounting unit 73 than to inspect the wafers W in the coating and developing treatment system 1, in terms of being capable of reducing the frequency of bypassing the wafer inspection apparatus 71 in other lots. A concrete example will be described below using FIG. 8.

FIG. 8(a) illustrates a state in which sixth and seventh wafers in a lot X and first to fifth wafers W in a lot Y are housed in the wafer mounting unit 73 which is capable of housing, for example, seven wafers, namely, a state in which there is no vacancy. When “Y6” being a sixth wafer W in the lot Y is delivered to the wafer transfer mechanism 70, the controller 300 determines, from the state in FIG. 8(a), that there is no vacancy in the wafer mounting unit 73, and the wafer W being “Y6” is transferred to the cassette Ca (S4 in FIG. 7) and “Y1” to “Y5” being other wafers W in the lot Y temporarily stored in the wafer mounting unit 73 are also collected into the cassette Ca before they are inspected in the wafer inspection apparatus 71. Further, a wafer W of “Y7” being a seventh wafer in the lot Y which has been subjected to exposure processing on the exposure stage 13a is also collected into the cassette Ca without being transferred to the wafer inspection apparatus 71 or the wafer mounting unit 73, for example, after it is delivered to the wafer mounting unit 70. In this vent, a wafer W in the lot X which has not bypassed the wafer inspection apparatus 71 is left as it is in the wafer inspection apparatus 71. This leads to, for example, a state in which only the wafers W in the lot X are stored in the wafer mounting unit 73 as illustrated in FIG. 8(b).

Thereafter, for example, as illustrated in FIG. 8(c), the wafers W in the lot X in the wafer mounting unit 73 are sequentially transferred to the wafer inspection apparatus 71, and wafers W in a subsequent lot Z are temporarily stored in the wafer mounting unit 73. In this event, since the wafers W in the lot Y have already been transferred out of the wafer mounting unit 73, the wafer mounting unit 73 becomes a state in which vacancies for the wafers W in the subsequent lot Z are ensured. Therefore, bypassing the wafer inspection apparatus 71 due to no vacancy in the wafer mounting unit 73 never occurs in the lot Z. Accordingly, speedily transferring the wafers W in the lot Y in which the wafer W bypassing the wafer inspection apparatus 71 has occurred, out of the coating and developing treatment system 1, makes it possible to suppress occurrence of wafers W bypassing the wafer inspection apparatus 71 in the subsequent lot Z. As a result, it is possible to efficiently perform inspection of the wafer W in the coating and developing treatment system 1.

Note that the timing when determining the presence or absence of a vacancy in the wafer mounting unit 73 by the controller 300 is not limited to after the wafer W is delivered to the wafer transfer mechanism 70 but may be before the wafer W is delivered to the wafer transfer mechanism 70, and the determination can be made at any timing such as after the wafer W is transferred out of, for example, the thermal treatment apparatus 40. Further, the decision whether or not to bypass the wafer inspection apparatus 71 when the controller 300 has determined that there is no vacancy in the wafer mounting unit 73 only needs to be made after completion of the inspection of the wafer W which is being performed in the wafer inspection apparatus 71 at that point in time, and the wafer W does not need to be transferred to the cassette Ca immediately at the point in time when it is determined that there is no vacancy in the wafer mounting unit 73. Even when it is determined that there is no vacancy in the wafer mounting unit 73, if a vacancy occurs in the wafer inspection apparatus 71 or the wafer mounting unit 73 because the inspection in the wafer inspection apparatus 71 is completed before a subsequent wafer W is transferred, the wafer W is transferred to the vacant place and thereby becomes unnecessary to bypass the wafer inspection apparatus 71.

Further, also when, for example, an abnormality occurs in any one of the wafer inspection apparatuses 71, 72 and therefore the one wafer inspection apparatus has become unusable any longer, the inspection of the wafer W which will be transferred to the unusable inspection apparatus may be stopped and transferred to the cassette Ca in the cassette station 10 while bypassing the wafer inspection apparatus 71. In this case, wafers W in the same lot with the wafer W which will be transferred to the unusable inspection apparatus may be transferred to the cassette Ca in the cassette station 10 without being transferred to the wafer inspection apparatus in which the abnormality has occurred. When any one of the wafer inspection apparatuses 71, 72 has become unusable any longer, both of inspected and uninspected wafers W in the same lot which have been under inspection in the unusable wafer inspection apparatus are inspected in a batch in another inspection apparatus outside the coating and developing treatment system 1, and its result is fed back to the exposure apparatus 13 side. In this case, the controller 300 may determine whether or not the wafer inspection apparatus 71, 72 is in a normal state (T1 in FIG. 7) prior to the determination whether or not the wafer inspection apparatus 71, 72 is in a vacant state to be able to inspect the wafer W (S1 in FIG. 7).

Preferred embodiments of the present invention have been described above with reference to the accompanying drawings, but the present invention is not limited to the embodiments. It should be understood that various changes and modifications are readily apparent to those skilled in the art within the scope of the spirit as set forth in claims, and those should also be covered by the technical scope of the present invention. The present invention is not limited to the embodiments but can take various forms. Further, the above-described embodiments are examples in the coating and developing treatment system for the semiconductor wafer, and the present invention is also applicable to the case of a coating and developing treatment system for other substrates such as an FPD (Flat Panel Display), a mask reticle for a photomask and the like other than the semiconductor wafer.

### INDUSTRIAL APPLICABILITY

The present invention is useful in inspecting a substrate after exposure processing.

### EXPLANATION OF CODES

1 coating and developing treatment system
10 cassette station
11 treatment station
12 interface station
13 exposure apparatus
20 cassette mounting table
21 cassette mounting plate
22 transfer path
23 wafer transfer apparatus
30 lower anti-reflection film forming apparatus
31 resist coating apparatus
32 upper anti-reflection film forming apparatus
33 developing treatment apparatus
40 thermal treatment apparatus
41 adhesion apparatus
42 edge exposure apparatus
70 wafer transfer mechanism
71, 72 wafer inspection apparatus
73, 74 wafer mounting unit
80 wafer transfer mechanism
90 wafer transfer mechanism
300 controller
W wafer
Dw wafer transfer region
Ca cassette

What is claimed:

1. A substrate treatment system for treating a substrate, comprising:
a treatment station in which a plurality of treatment apparatuses that treat the substrate are provided;
an interface station which delivers the substrate between the treatment station and an exposure apparatus which is provided outside the substrate treatment system and comprises a plurality of exposure stages;
a plurality of substrate inspection apparatuses which perform inspection of a substrate front surface;
a substrate transfer mechanism which transfers the substrate between each of the treatment apparatuses in the treatment station and the substrate inspection apparatus; and
a controller which controls the substrate transfer mechanism,
wherein the controller is configured to identify an exposure stage which has been used in exposure processing of a substrate transferred out of the exposure apparatus, from among the plurality of exposure stages, and control the substrate transfer mechanism to transfer the substrate after the exposure processing to a substrate inspection apparatus previously made to correspond to the identified exposure stage.

2. The substrate treatment system according to claim 1,
wherein the controller is configured to control the substrate transfer mechanism to transfer the substrate after the exposure processing to the substrate inspection apparatus via a treatment apparatus previously made to correspond to the identified exposure stage.

3. The substrate treatment system according to claim 1, further comprising:
a substrate mounting unit which temporarily stores a plurality of substrates therein,
wherein the controller is configured to control, when the substrate inspection apparatus is in use and a substrate is not allowed to be transferred to the substrate inspection apparatus, the substrate transfer mechanism to temporarily store the substrate which is not allowed to be transferred to the substrate inspection apparatus, in the substrate mounting unit.

4. The substrate treatment system according to claim 3,
wherein the controller is configured to stop, when a number of substrates stored in the substrate mounting unit has reached an upper limit of a storage capacity and therefore the substrate which is not allowed to be transferred to the substrate inspection apparatus is not allowed to be stored in the substrate mounting unit, the inspection in the substrate inspection apparatus on the substrate which is not allowed to be stored and substrates in a same lot with the substrate which is not allowed to be stored.

5. The substrate treatment system according to claim 4, further comprising:
a cassette station comprising: a cassette mounting unit on which a cassette that houses a plurality of substrates is mounted; and another substrate transfer mechanism which transfers the substrate between the treatment station and the cassette mounting unit,
wherein the controller is configured to control, when the inspection in the substrate inspection apparatus is stopped, the substrate transfer mechanism and the another substrate transfer mechanism to transfer a substrate on which the inspection is stopped and substrates in a same lot with the substrate, to the cassette while bypassing the substrate inspection apparatus.

6. The substrate treatment system according to claim 1, further comprising:
a cassette station comprising: a cassette mounting unit on which a cassette that houses a plurality of substrates is mounted; and another substrate transfer mechanism which transfers the substrate between the treatment station and the cassette mounting unit,
wherein the controller is configured to control, when the substrate inspection apparatus is unusable due to an abnormality, the substrate transfer mechanism and the another substrate transfer mechanism to transfer a substrate which has been subjected to exposure processing on the exposure stage previously made to correspond to the substrate inspection apparatus and substrates in a same lot with the substrate, to the cassette while bypassing the substrate inspection apparatus.

7. The substrate treatment system according to claim 1,
wherein the substrate inspection apparatus is a measuring apparatus which measures an overlay error.

8. The substrate treatment system according to claim 1,
wherein the substrate inspection apparatus is disposed in the treatment station.

9. A method for transferring a substrate in a substrate treatment system for treating a substrate,
the substrate treatment system comprising:
a treatment station in which a plurality of treatment apparatuses are provided;
an interface station which delivers the substrate between the treatment station and an exposure apparatus which is provided outside the substrate treatment system and comprises a plurality of exposure stages;
a plurality of substrate inspection apparatuses which perform inspection of a substrate front surface; and
a substrate transfer mechanism which transfers the substrate between each of the treatment apparatuses in the treatment station and the substrate inspection apparatus,
the substrate transfer method comprising:
identifying an exposure stage which has been used in exposure processing of a substrate transferred out of the exposure apparatus, from among the plurality of exposure stages, and transferring the substrate after the exposure processing to a substrate inspection apparatus previously made to correspond to the identified exposure stage.

10. The substrate transfer method according to claim 9,
wherein the substrate after the exposure processing is transferred to the substrate inspection apparatus via a treatment apparatus previously made to correspond to the identified exposure stage.

11. The substrate transfer method according to claim 9,
wherein the substrate treatment system further comprises a substrate mounting unit which temporarily stores a plurality of substrates therein, and
wherein when the substrate inspection apparatus is in use and a substrate is not allowed to be transferred to the substrate inspection apparatus, the substrate which is not allowed to be transferred to the substrate inspection apparatus is temporarily stored in the substrate mounting unit.

12. The substrate transfer method according to claim 11,
wherein when a number of substrates stored in the substrate mounting unit has reached an upper limit of a storage capacity and therefore the substrate which is not allowed to be transferred to the substrate inspection apparatus is not allowed to be stored in the substrate mounting unit, the inspection in the substrate inspection apparatus on the substrate which is not allowed to be stored and substrates in a same lot with the substrate which is not allowed to be stored, is stopped.

13. The substrate transfer method according to claim 12,
wherein the substrate treatment system further comprises a cassette station comprising: a cassette mounting unit on which a cassette that houses a plurality of substrates is mounted; and another substrate transfer mechanism which transfers the substrate between the treatment station and the cassette mounting unit, and
wherein when the inspection in the substrate inspection apparatus is stopped, a substrate on which the inspection is stopped and substrates in a same lot with the substrate are transferred to the cassette while bypassing the substrate inspection apparatus.

14. The substrate transfer method according to claim 9,
wherein the substrate treatment system further comprises a cassette station comprising: a cassette mounting unit on which a cassette that houses a plurality of substrates is mounted; and another substrate transfer mechanism which transfers the substrate between the treatment station and the cassette mounting unit, and
wherein when the substrate inspection apparatus is unusable due to an abnormality, a substrate which has been subjected to exposure processing on the exposure stage previously made to correspond to the substrate inspection apparatus and substrates in a same lot with the substrate are transferred to the cassette while bypassing the substrate inspection apparatus.

15. The substrate transfer method according to claim 9,
wherein the substrate inspection apparatus is a measuring apparatus which measures an overlay error.

16. The substrate transfer method according to claim 9,
wherein the substrate inspection apparatus is disposed in the treatment station.

17. A computer readable storage medium storing a program running on a computer of a control apparatus controlling a substrate treatment system to cause the substrate treatment system to execute a substrate transfer method,
the substrate treatment system comprising:
a treatment station in which a plurality of treatment apparatuses are provided;
an interface station which delivers a substrate between the treatment station and an exposure apparatus which is provided outside the substrate treatment system and comprises a plurality of exposure stages;
a plurality of substrate inspection apparatuses which perform inspection of a substrate front surface; and
a substrate transfer mechanism which transfers the substrate between each of the treatment apparatuses in the treatment station and the substrate inspection apparatus, and
the substrate transfer method comprising identifying an exposure stage which has been used in exposure processing of a substrate transferred out of the exposure apparatus, from among the plurality of exposure stages, and transferring the substrate after the exposure processing to a substrate inspection apparatus previously made to correspond to the identified exposure stage.
